(19) United States
(12) Patent Application Publication
(10) Pub. No.: US 2026/0277028 A1
(43) Pub. Date: Sep. 17, 2026

(54) Biometric System Disruption Eyeglasses Frames And Methods

(71) Applicant: David Vitalli, Brentwood, TN (US)

(72) Inventor: David Vitalli, Brentwood, TN (US)

(21) Appl. No.: 19/395,824

(22) Filed: Nov. 20, 2025

Related U.S. Application Data
(63) Continuation-in-part of application No. 19/334,599, filed on Sep. 19, 2025.
(63) Continuation-in-part of application No. 19/334,594, filed on Sep. 19, 2025.
(63) Continuation-in-part of application No. 19/081,505, filed on Mar. 17, 2025, now abandoned.

(51) Int. Cl. G02C 11/00; G01J 1/42; G02C 5/00; G02C 5/02; G02C 5/14; H05B 45/10; H05B 45/20; H05K 7/20

(52) U.S. Cl. CPC G02C 11/10; G01J 1/4204; G02C 5/001; G02C 5/02; G02C 5/14; H05B 45/10; H05B 45/20; H05K 7/20127

(57) ABSTRACT

A biometric privacy protection eyewear system comprising an eyeglass frame housing a plurality of infrared (IR) light-emitting diodes operating between approximately 780 and approximately 1100 nanometers, at least one sensor, a control microcircuit, a power source, temperature modulation features, and IR emitters that provide optical interference patterns that disrupt facial-recognition and depth-sensing cameras and which can prevent unauthorized biometric data capture.

### CROSS REFERENCE TO RELATED APPLICATIONS

This application claims the benefit of U.S. Ser. No. 19/081,505, filed on Mar. 17, 2025, and it is a continuation-in-part of U.S. Ser. No. 19/334,594 and U.S. Ser. No. 19/334,599, both filed on Sep. 19, 2025, which are each hereby incorporated by reference herein in their entirety.

### FIELD OF THE INVENTION

The present invention relates to biometric privacy protection systems, and more particularly to eyewear that utilize controlled infrared emission between approximately 780 nanometers and approximately 1100 nanometers to prevent unauthorized facial recognition, depth mapping, or biometric data capture by digital imaging systems.

### BACKGROUND OF THE INVENTION

Facial recognition technology and other biometric systems are widely used in surveillance, security, and personal devices. While beneficial in various applications, they raise concerns about privacy and unauthorized surveillance. Conventional anti-surveillance methods, such as masks or tinted visors, can draw attention and can be impractical for everyday wear in some situations. This invention provides a discreet and highly effective means of counteracting biometric systems, such as facial recognition systems, including their algorithms, while maintaining the aesthetics and functionality of various types of standard-looking eyeglasses.

Problems exist in the art because current IR devices are not discreet and safe and they do not provide sustainable and wearable disruption of facial recognition and other biometrics.

Solutions to these problems are provided by certain embodiments of this invention with an integrated stealth form factor, pulse width modulation and thermal feedback, artificial intelligence and/or random modulation of the IR emissions, and multi-angle IR coverage. The result of the invention in certain embodiments is reliable biometric system (e.g., facial recognition) sensor corruption that is also immune to artificial intelligence correction.

### SUMMARY OF THE INVENTION

The invention provides a personal privacy protection system designed to safeguard individuals from unconsented biometric scanning, facial recognition, and image-based identification. The system in certain embodiments includes an eyeglass frame integrated with a plurality of eye-safe infrared (IR) light-emitting diodes (LEDs) operating within a spectral range of approximately 780 nanometers to approximately 1100 nanometers, one or more sensors (e.g., ambient-light sensors), and a control microcircuit, which can be configured in certain embodiments to dynamically adjust IR output intensity and pattern according to surrounding light conditions.

The system operates from an independent power source in certain embodiments that is not physically connected to the eyewear frame during normal use. The emitted IR light creates targeted interference patterns that disrupt facial-recognition cameras, depth sensors, and other imaging systems, thereby preventing unauthorized collection or processing of biometric data.

The emitters produce minimal heat output under sustained operation; however, the eyewear frame is provided with temperature modulation features that can comprise vents, as an example, to provide additional passive cooling and maintain long-term comfort and safety. In certain embodiments, the device functions strictly as a defensive privacy measure—it does not record, store, or transmit information, nor does it damage or permanently impair any imaging system.

The device provides users with a lawful means of maintaining personal privacy in environments where cameras, AI-based recognition systems, and augmented-reality devices may otherwise capture and analyze facial features without consent. All emission parameters remain within established international eye-safety limits (IEC 62471, ISO 15004), ensuring continuous safe operation under daylight and low-light conditions.

Certain embodiments comprise a wearable biometric-privacy protection system comprising: an eyeglass frame or wearable support structure; a plurality of infrared light-emitting diodes configured to emit within a spectral range of approximately 780 nanometers to approximately 1100 nanometers; at least one ambient-light sensor configured to detect surrounding illumination intensity; a control circuit and microcontroller configured to dynamically modulate the infrared output, including emission intensity, wavelength selection, and emission pattern, in response to real-time ambient light data; a vented frame structure designed for passive thermal management; an independent or detachable power source electrically connected to the control circuit; and wherein the emitted infrared light interferes with image sensors, facial-recognition systems, and depth-mapping technologies to prevent unauthorized biometric capture of the wearer while maintaining compliance with international eye-safety standards. In certain of these embodiments, (a) the infrared emitters are arranged in multiple arrays oriented at different angles to provide multidirectional coverage (b) the emission modulation comprises pattern-based or stochastic sequences designed to disrupt rolling-shutter and structured-light image processing, (c) the control circuit increases infrared output intensity in response to detected high ambient illumination to maintain effective interference under daylight conditions, (d) the power source is rechargeable and detachably mounted, (e) the vented frame comprises heat-dissipation channels designed to maintain the temperature of the eyewear within safe user-contact limits, (f) the emitted infrared light operates across dual bands of (i) approximately 780 nanometers and (ii) approximately 940 nm to approximately 1100 nm, to provide effective disruption of both camera and depth-sensing systems, and/or (g) the device includes safety interlocks preventing emission above IEC 62471 thresholds.

This invention as applied can have several significant differences from prior systems and methods. Certain embodiments of this invention use active, adaptive, and closed-loop control rather than static IR emissions of previous systems. In addition, these embodiments can be emissive, and not reflective, like previous attempts, and also be provided with electronic modulation and spectral tuning. Furthermore, these embodiments can provide sustained, daylight-effective operation, with effective power management and heat regulation. This can also include adaptive modulation, spectral breadth, vented integration, and/or safety regulation within a single wearable platform. Moreover, these embodiments can provide a specific technical solution to a technical problem—i.e., unauthorized biometric data capture in varying illumination environments—that previous systems are unable to provide.

In certain embodiments, the invention integrates an IR LED emitter array within eyeglasses frames to obscure critical facial landmarks required for biometric systems, such as facial recognition, so that the design ensures a method of use that provides adequate to maximum coverage, effective disruption (e.g., interference), and long-term comfort through optimized heat dissipation and power management.

Examples of embodiments of the present invention overcome the limitations of the past by integrating infrared technology into a standard-looking eyeglasses frames, providing continuous and undetectable disruption to camera apparatus and/or associated algorithms while remaining aesthetically neutral. Applied infrared light obscures facial features visible to camera apparatus (e.g., obscures facial features that recognition algorithms rely on to make comparisons and identifications). In particular, the infrared light in certain embodiments may overexpose and/or distort facial features in camera images and/or data and render facial recognition less effective. The invention overcomes the drawbacks of certain conventional privacy protection methods.

Certain embodiments of the eyeglasses frames of this invention comprise a pair of prescription-compatible eyeglasses (non-prescription and prescription lenses can both be used) featuring an infrared light disruption system integrated into a discreet, modern frame. These embodiments can provide continuous and undetectable disruption to cameras while appearing aesthetically neutral.

Certain embodiments of the eyeglasses frame maintain the appearance of standard eyeglasses frames while incorporating the functionality described herein.

Certain of the examples of embodiments comprise particular components, features and uses (some of which can be combined in one or more components or separated into two or more components that achieve the same functions and results):

### I. IR LED Emitter Components, Features And Use:

These examples of embodiments use multiple IR LED emitters. In some embodiments, these are distributed along the top (e.g., upper rim) of the front of an eyeglasses frame, the bottom of the frames, the sides of an eyeglasses frame, or combinations of such, or otherwise pointed at or emitting around the face (e.g., providing IR light between a person and a facial recognition system), to enhance facial landmark disruption. Other configurations of the multiple IR LED emitters can be used.

An examples of number of IR LED emitters is between 2 and 24, although more (and less) can be used in some applications. Examples of number of IR LED emitters is between 10 and 20, and another example of number of IR LED emitters is between 16 and 18. Other examples of number of IR LED emitters in some applications is between 8 and 12. It should be understood, however, that this invention is not limited to a certain number of IR LED emitters.

The wavelength emitted from the multiple IR LED emitters can vary in different embodiments and any IR emission or combinations of emissions can be used. One examples of range is from about 780 nm to about 1100 nm of the near-infrared spectrum. Another example of range is from about 780 nm to about 950 nm of the near-infrared spectrum. Another example of range is from about 850 nm to about 940 nm. Another example of range is from about 850 nm to about 1100 mn. In certain examples of embodiments, the IR LED emitters emit at about 850 nm wavelength, which is invisible to the human eye but effective against facial recognition cameras.

In other examples of embodiments, the IR LED emitters emit at about 940 nm. In other certain examples of embodiments, the eyeglasses frames use a combination of IR LED emitters, such as some IR LED emitters that emit at about 850 nm wavelength and other IR LED emitters that emit at about 940 nm wavelength. Certain IR LED emitters can be used that emit at multiple wavelengths Other combinations of IR LED emitters that emit at different wavelengths can be used in some applications.

In certain embodiments, the IR LED emitters have an approximately 120-degree beam angle to ensure a fulsome facial coverage or other desired effect. Other beam angles or emitting features, and different combinations of such, also can be used to obtain effective facial coverage or other desired effect.

The invention permits flexibility in how the IR emitters are arranged and their angles of coverage. Thus, the disruption provided by this invention can apply regardless of the emitter orientation (e.g., regardless of angular positioning of the IR emitters, including downward, upward, outward, diagonal, or dynamically adjustable) as long as there is sufficient coverage to provide disruption.

### II. Power Management and Battery Components, Features and Use:

The power source should provide sufficient power (e.g., a battery with a capacity of about 100 mAh to about 1000 mAh, or between about 300 mAh to about 500 mAh in other embodiments), be long-lasting operation, and have effective heat management, while fitting compactly into an eyeglasses frame arm or other component.

An exemplary embodiment uses 8 to 12 IR LED emitters, a battery capacity of about 300 mAh to about 500 mAh, which produces an estimated runtime of about 3 to about 5 hours of continuous use, and about 5 to about 7 hours in a power-saving mode. Other embodiments with three IR LED emitters have a battery capacity of about 100 mAh and an estimated runtime of continuous use of about 1 to about 2 hours.

Battery integration into the eyeglasses frame can in some embodiments include embedding a 300-500 mAh lithium ion battery inside the eyeglasses frame arm, routing the power cables discreetly through the hinge areas to the IR LED emitters, use of a microcontroller to regulate the LED intensity dynamically, and including use of a compact Battery Management System (BMS) board to protect against overcharging and heat issues. Other batteries and arrangements of components can be used.

Certain examples of embodiments use high-capacity lithium-ion (or lithium-pulse) rechargeable batteries (e.g., a capacity to accommodate multiple IR LED emitters and their functions).

Certain examples of batteries include lithium-ion or lithium-polymer batteries, with a capacity of 300 mAh to 500 mAh, voltage of 3.7V, ultrathin and flexible batteries (e.g., about 4 to about 6 mm thick and about 40 mm in length) to fit within the eyeglasses frame's arm.

Certain embodiments use a USB-C charging port (or other charging port) integrated into the eyeglasses frame arm (e.g., underside, interior), with the port in some embodiments discreetly integrated into the eyeglasses frame arm, and for discreet recharging.

Certain embodiments use an Advanced Power Controller (APC) integrated circuit that dynamically adjusts the IR LED emitters' intensity to balance battery life, power consumption and effectiveness.

Certain embodiments use a Battery Management System (BMS) that prevents overheating and optimizes battery life. Examples of embodiments of the BMS include (a) a smart power controller that dynamically adjusts IR LED intensity to conserve the battery, (b) overcharge protection to ensure safe recharging via the USB-C port; (c) thermal sensors to monitor temperature and regulate power to prevent overheating; and (d) an auto-shut-off feature when the IR LED emitters are inactive, which saves power.

Certain embodiments provide power distribution to the IR LED emitters that is maintained at a steady output (e.g., 3.7V) for consistent IR LED brightness. Current-limiting resistors are used to prevent excess power draw from the IR LED emitters. A Pulse Modulation Controller integrated circuit (PWM Control, or Pulse Modulation Controller module) can also be used in some embodiments and it operates to provide pulses of IR light from the IR LED emitters, which reduces continuous power drain and extends battery life.

Certain embodiments provide these pulses or intermittent use of IR light from the IR LED emitters that may be efficient and effective in disrupting camera-based facial recognition. These can include random pulses, non-random pulses, time-based pulses, combination pulses, other types of pulses and intermittent use (e.g., varying intensity, varying wavelength) and/or combinations of these. Some embodiments permit the user to choose what type of pulse, if any, is used by a switch or other selection component. Other embodiments may include manual, automatic, and/or artificial intelligence (“AI”) controlled switching of pulses (e.g., switching from non-random to time-based) to disrupt camera-based facial recognition systems. One or more of the circuits/controllers identified above (e.g., PCB, APC Controller, PWM Control) alone or together can provide this capability. Some embodiments can also apply AI and/or algorithms to adapt and respond to a given power, battery, facial recognition system, and/or other environmental situation.

Certain embodiments have camera detectors, or camera-likelihood detectors, from the current location, known camera placements (e.g., public areas), surroundings, detection of IR focusing means, image sensors, lens reflections, etc., that can be used to turn the device on or off or select a type of emission or other mode (e.g., wavelength, intensity, pulse or non-pulse or combination). In certain examples of embodiments, the IR emission method used is one that will disrupt the actual camera-based facial recognition of interest and/or that is likely to be encountered.

Examples of embodiments of this invention use active, real-time disruption with the components described herein. The threat from software, AI or other means adapting to IR interference devices and overcoming any disruption to still provide reconstructed facial data is overcome by certain embodiments of this invention on the hardware level because they effectively disrupt the raw visual input to the facial recognition system itself.

Certain of the examples of embodiments provide flash sequences of the infrared lights that operate in a continuous loop. Each cycle of the ignition sequence generates a unique light pattern that is randomized or altered from the previous cycle. This ensures that the flashing behavior cannot be predicted, mapped, or adapted to by external imaging or AI-based recognition systems.

Some of the examples of embodiments have an increased number of LEDs for more effective facial coverage and a battery system that provides sufficient power, long-lasting operation, and effective heat management while fitting compactly into the eyeglass frame arm.

Certain of the examples of embodiments embed an 300 mAh-500 mAh Li-Ion battery discreetly inside the eyeglasses frame arm. In these embodiments, the power cables are run discreetly through the eyeglasses hinge area to the LEDs. They also use a microcontroller to regulate LED intensity dynamically and include a compact BMS board to protect against overcharging and heat issues.

### III. Heat Dissipation and Safety Components, Features and Use:

These examples of embodiments use integrated ventilation slots (e.g., openings) and micro-perforations along the top of the front of the eyeglasses frames, or in other effective placements, to regulate heat.

Certain embodiments use temperature regulation sensors (e.g., in conjunction with a Printed Circuit Board (PCB) and/or the APC) that actively monitor IR LED heat levels and adjust output accordingly.

Certain embodiments use adaptive thermal modulation systems to prevent thermal buildup while preserving performance, which is controlled by an onboard microcontroller. The microcontroller actively monitors the temperature of the IR LED diodes (via integrated thermistors or diode junction temperature sensing) and dynamically adjusts the strobe pulse frequency and duty cycle of the LED driving signals. Rather than driving the LEDs in steady-state, the controller drives them in a rapid pulsed IR strobe within a range of approximately 5-20 Hz. This means the IR LED emitters blink on and off faster than the human eye can perceive (infrared being invisible regardless), but fast enough to appear as a near-constant flood to a camera. The duty cycle (the ON vs. OFF time ratio of each pulse) is modulated based on real-time temperature feedback: if the LEDs' temperature approaches a defined threshold, the controller automatically shortens the ON duration or lengthens the OFF interval of pulses to reduce heat accumulation. Conversely, when temperature is within safe limits, the system can use a higher duty cycle (longer pulses) to maximize IR output. This adaptive Pulse Width Modulation or PWM-based drive ensures the LEDs operate within safe thermal limits at all times, avoiding overheating or damage.

In these embodiments, the adaptive logic leverages PWM thermal management techniques: temperature sensors feed into a control loop that adjusts LED PWM duty cycle to counteract any rise in junction temperature. By reducing the duty cycle when the LEDs get too warm, the system lowers the average power dissipation (allowing the diodes to cool) while still emitting periodic IR flashes. This approach improves the stability and reliability of the IR emitters under all conditions, effectively extending LED lifespan and preventing performance degradation. In summary, the adaptive thermal modulation ensures that the anti-recognition glasses deliver a consistent, effective IR output for facial masking, without overheating, through intelligent real-time adjustment of strobe frequency and duty cycle based on LED temperature. This guarantees that the device remains safe and functional over prolonged use, all while maintaining its full disruptive capability against facial recognition systems.

Certain embodiments use an eyeglasses frame that is constructed from heat-resistant, thermally conductive polymer for enhanced durability and comfort. Thus, thermally conductive, heat-resistant, IR-transparent and/or IR-diffusing materials are examples of materials for the frames. Thus, examples of frame and housing material are selected for thermal conductivity, infrared transparency or diffusion, and structural integrity under sustained heat output.

### IV. Other Design and Aesthetic Components, Features and Use:

These examples of embodiments use flush-mounted IR LED emitters to ensure that the eyeglasses frame, maintains a low-profile, everyday appearance. However, other IR LED placements and types (e.g., flush-mounted, dome-type, surface-mounted, lens-containing) and combinations of such can be used.

Certain embodiments use a matte black finish for the components and/or the frames that minimizes reflections and enhances discretion.

Certain embodiments use a lightweight ergonomic structure of the eyeglasses frame that ensures comfortable extended wear (e.g., about 3 or more hours without discomfort).

Certain embodiments also use optical filters, reflectors, or lens coatings (e.g., as the lenses in eyeglasses frames) as non-emissive methods to reduce the efficacy of any facial recognition system or device.

Embodiments of eyeglass frames may comprise material-level protection for frame polymers. Thus, thermally conductive, heat-resistant, IR-transparent, and/or IR-diffusing materials can be used. In certain of these embodiments, the frame or housing material is selected for thermal conductivity, infrared transparency or diffusion, and/or structural integrity under sustained heat output.

Certain of the examples of embodiments comprise an expansive 850 nm wavelength, 120-degree beam angle IR LED array, an optimized power source, advanced heat dissipation, and enhanced ergonomic features that are highly effective against facial recognition, ensure better battery life, and maintain aesthetic discretion.

V. Combinations with Other Biometric System Disrupters

The eyeglasses frames embodiments of this invention can be combined with other components and/or methods to achieve additional biometric system disruption. These include voice manipulators (e.g., pitch alteration, muffling, or voice-altering software and components that evade automatic speaker verification systems) and other facial, mannerism, or additional body part obfuscation (e.g., side profile alteration, photoplethysmography alteration (PPG), heavy makeup, wigs, fingerprint alteration, eye changes, gaze alteration, gate changes, mood detection changes, iris or retina pattern changes (e.g., special contact lenses)).

This invention establishes and can be used in a platform for integration across multiple consumer privacy applications, including other types of eyewear, clip-on modules, head-mounted accessories, and protective enclosures for camera-observable environments. The adaptive infrared interference principles described herein can be applied to personal privacy systems, vehicular driver-monitoring disruption, and anti-surveillance consumer accessories, subject to jurisdictional compliance and safety standards.

Thus, in certain of these embodiments, protection against biometric data harvesting beyond facial recognition is also provided. This may include disruption of eye-tracking, gaze analysis, 3D depth mapping, iris scans, and/or other biometric data collection techniques. In some of these embodiments, the device is configured to interfere with, obstruct, and/or degrade acquisition of biometric data including but not limited to facial recognition, gaze tracking, iris scanning, 3D depth mapping, and/or photoplethysmography.

### VI. Selected Examples of Embodiments

In certain examples of embodiments, eyeglasses frames that disrupt facial landmark detection by a facial recognition system are provided. The eyeglasses frames comprise: (a) a front part of the eyeglasses frame, with a top of the front part, the eyeglasses frames also having two arms, a left arm and a right arm, each of the arms attached to the front part by a hinge; (b) multiple IR LED emitters (e.g., approximately 780 nm and/or approximately 940 nm, or another IR wavelength, having 120-degree beam angles or other conformations), each IR LED emitters embedded into and mounted flush with, and positioned along, the top of the front part of the eyeglasses frame; (c) a power source for providing power to each of the IR LED emitters, the power source comprising multiple power source components that work in concert.

The power source components in these embodiments comprise: (i) a high-capacity rechargeable lithium battery, which battery is integrated within the eyeglasses frame, and which battery provides power that is used by each of the IR LED emitters; (ii) a USB-C charging interface, which charging interface is positioned within an arm of the eyeglasses frame, and which charging interface charges the battery; (iii) a battery management system, which battery management system is integrated within the eyeglasses frame and is connected to the battery, and which battery management system works with other power source components to regulate power distribution, intensity of each of the IR LED emitters, and heat dissipation; (iv) multiple heat dissipators, the dissipators comprising ventilation slots and micro-perforations in the top of the front part of the eyeglasses frame that dissipate heat to prevent overheating of each of the IR LED emitters; (v) temperature regulation sensors, which sensors are embedded in the front part of the eyeglasses frame, and which sensors work with other power source components to adjust the output of each of the IR LED emitters based on temperature to prevent overheating of each of the IR LED emitters; (vi) a dynamic power controller that work with other power source components to adjust the intensity of each of the IR LED emitters to maximize facial recognition disruption while preserving battery life; and (vii) an electrical circuit connecting the battery, charging interface, battery management system, sensors, controller, and each of the IR LED emitters.

These embodiments also have an eyeglasses frame that comprises: (a) a matte black finish to provide aesthetic discretion; (b) heat-resistant, thermally conductive polymer for durability and comfort; and (c) wherein the multiple IR LED emitters of the eyeglasses frame disrupt the facial landmark detection by the facial recognition system under various light conditions.

In these embodiments, certain examples of embodiments of these are where (a) the battery is a lithium-ion or lithium-polymer battery with a capacity of about 300 mAh to about 500 mAh, a voltage of about 3.7V, and is about 4 mm to about 6 mm thick and about 40 mm in length; (b) the battery management system further provides overcharge protection to ensure safe recharging and an automatic shut-off of each of the IR LED emitters when they are inactive to save power; (c) the battery management system and the dynamic power controller are provided on a single printed circuit board; (d) the power source further comprises a voltage regulator that maintains a steady approximately 3.7V output for each of the IR LED emitters; (e) the power source further comprises current-limiting resistors that prevent excess power draw from each of the IR LED emitters; (f) the power source further comprises pulse modulation control that provides pulsing IR LED operation to reduce continuous power drain and extend battery life; and/or (g) the power source further comprises a power-saving mode that limits the intensity and/or duration of IR LED use to extend battery life.

Each of these examples of embodiments of the eyeglasses frames can be used in methods of disrupting facial landmark detection by a facial recognition system. These methods use the examples of embodiments of the eyeglasses frames provided above and comprise: (a) wearing one of the eyeglasses frames comprising a power source that can be powered on to provide power to infrared light sources embedded in the eyeglasses frame; (b) powering on the eyeglasses frame to provide the power to the infrared light sources from the power source; (c) providing infrared light from infrared light sources towards the facial landmark detection by the facial recognition system; and (d) disrupting the facial landmark detection by the facial recognition system using the infrared light from the infrared light sources.

These examples of embodiments also can be used in other methods of disrupting facial landmark detection by a facial recognition system. These other methods use the examples of embodiments of the eyeglasses frames provided above and comprise: (a) providing pulses of infrared light to the person's face using one of the eyeglasses frames; and (b) disrupting the image of the person's face captured by the facial recognition system with the pulses of infrared light so that the facial recognition system fails to identify the person's face.

Advantages of this invention include that certain embodiments provide the first fully adaptive, eye-safe infrared emission system capable of protecting individuals from unconsented biometric data capture in real-world daylight conditions. Unlike prior devices that rely on passive reflection, fixed-intensity emission, or narrow spectral bands, this system actively adjusts its output across a broad spectrum of approximately 850 to approximately 1100 nanometers in response to ambient light variations.

The combination of ambient sensing, microcircuit control, and pattern-based emission ensures effective disruption of facial-recognition and depth-mapping technologies used in mobile devices, surveillance systems, and augmented-reality glasses. The system operates safely and efficiently with minimal heat output, requires no data connection or wireless control, and complies with all recognized eye-safety standards.

These advantages make the invention uniquely capable of maintaining user privacy without compromising comfort, safety, or usability, thereby establishing a new benchmark for personal biometric-privacy protection technology.

Additional advantages of the embodiments of this invention are described and apparent throughout this specification. For example, certain embodiments provide continuous interference with facial recognition systems, effectively overexposing camera sensors while remaining invisible to the naked eye. Unlike previous anti-surveillance solutions, the device ensures that privacy protection is seamless, discreet, and effective in a variety of lighting conditions. Other advantages of embodiments of this invention include that they can operate at the hardware level and thus disrupt raw visual input that can make the disruption harder to overcome by facial recognition systems. Thus, in these embodiments active disruption is a key feature. Further advantages will be apparent to a person of skill in the art practicing the teaching and the embodiments of the invention.

Additional features and advantages of various embodiments will be set forth in part in the description that follows, and in part will be apparent from the description, or may be learned by practice of various embodiments. The objectives and other advantages of various embodiments will be realized and attained by means of the elements and combinations particularly pointed out in the description and appended claims.

### BRIEF DESCRIPTION OF THE DRAWINGS

FIG. 1 is a perspective front-side view of an embodiment of the invention.

FIG. 2 is a perspective back-side view of an embodiment of the invention.

FIG. 3 is a perspective front-side view of additional embodiments of the invention worn on a person's head, including an embodiment with IR LED emitters on the front of the frames, and an embodiment with an IR LED on the side of the frames.

FIG. 4 is a schematic diagram showing certain component placement of an embodiment of the invention.

FIG. 5 is a schematic diagram showing connections between certain components of an embodiment of the invention.

FIG. 6 is a schematic diagram showing certain component placement in the left frame arm of an embodiment of the invention.

FIG. 7 is a diagram showing IR LED emitter placement in an embodiment of this invention.

FIG. 8 is a perspective front-side partial view of an embodiment of eyeglasses of the invention.

### DETAILED DESCRIPTION OF THE INVENTION

The invention provides eyeglasses frames that can disrupt biometric systems (e.g., facial recognition systems) and in some embodiments can comprise multiple (e.g., 8-22, but more or less can also be used) infrared LEDs that are infrared disrupters, heat dissipation, and a power source that includes a power controller, among other components, features and uses. The eyeglasses frames in certain embodiments can incorporate and/or be used in conjunction with additional biometric system disrupters.

In certain embodiments, eyeglasses frames useful for this invention generally comprise a left arm (or left temple) and a right arm (or right temple) that keep the eyeglasses on the face securely. They also include hinges, which allow the arms to fold inwards and they connect each of the arms to the front of the glasses. The front of the glasses have a left lens mount or rim, and a right lens mount or rim, that are joined in the middle by a bridge that connects them. The front of the glasses has a top portion that goes from one side to the other, and is referred to as the top of the front herein.

The invention also describes methods for discreetly counteracting facial recognition camera systems and their algorithms. These methods use the embodiments of the eyeglasses frames of this invention. Such methods provide for privacy protection against such systems

In the eyeglasses frames embodiments, a wide variety of eyeglasses frames can be used, and such eyeglasses frames generally comprise mounts for lenses (e.g., prescription lens or clear, non-prescription lenses) and in some embodiments have a finish, fit, and comfortable weight distribution. In certain embodiments, the eyeglasses frames are constructed using lightweight, heat-resistant polycarbonate or an alternative thermally conductive polymer and they have a matte black finish to enhance discretion. In some embodiments, the eyeglasses frames are sunglasses.

In certain embodiments, the eyeglasses frames include: (a) prescription-compatible lens mounts that are designed to accommodate standard prescription lenses; (b) a matte black or other finish to maintain a low-profile and stylish appearance; (c) an ergonomic fit, to help provide comfort for extended wear (e.g., for about 3 hours or more without significant discomfort); and/or (d) a comfortable or otherwise tolerable weight distribution that is carefully designed so that the battery and LEDs do not create too much discomfort for the user for extended wear.

The infrared disrupter used is some embodiments is comprised of IR LED components and in certain examples of embodiments they are comprised of multiple IR LED emitters that are of (a) certain types (e.g., high-efficiency, 850 nm IR LED emitters with a 120-degree beam angle), (b) a power output of each LED of between about 50 mW and about 1 W, and an example of power output of each LED of about 1 W, totaling 3 W across the device), (c) an example of placement with LEDs on the top of the front of the device or otherwise providing IR emissions to the face, (d) an example of activation mechanism (e.g., a concealed micro-switch within the arm of an eyeglasses frame), and (e) an example of operational duration (e.g., designed to last between about 1.5 to about 3 hours per charge, or longer, depending on usage and environmental conditions).

The eyeglasses frames in some embodiments include provisions (e.g., components, capabilities features) for heat dissipation. In certain embodiments the eyeglasses frames include heat dissipation provisions that comprise one or more of: (a) ventilation slots (e.g., slots strategically placed along the top of the front of the frames to dissipate heat from the IR LED emitters), (b) micro-perforations (e.g., micro-perforations along the top of the frame to allow passive airflow over the embedded components), (c) an advantageous material choice (e.g. a thermally conductive composite that helps distribute heat away from sensitive areas), and/or (d) temperature regulation sensors (e.g., sensors that are integrated to monitor and prevent overheating beyond safe or uncomfortable limits by adjusting the infrared disrupter and/or to maximize battery life).

The eyeglasses frames in some embodiments include provisions (e.g., components, capabilities, features) for providing power and charging. This may comprise (a) one or more batteries (e.g., one or more rechargeable lithium-ion batteries, each embedded in the frame arm, and in some embodiments one 3.7V lithium-ion rechargeable battery with a capacity of about 300 mAh to about 500 mAh), (b) one or more charging ports (e.g., a concealed USB-C port, located on the underside of one frame arm), (c) efficient power use by operation of a power controller (e.g., a printed circuit board design that balances IR disrupter power consumption with maximum facial recognition disruption while maintaining a safe temperature or temperature range), (d) a micro-switch (e.g., a low-profile switch on the inner surface of a frame arm), and (e) automatic power control using the power controller (e.g., an auto-shutoff function when the device is inactive to preserve battery life). A battery management system (BMS) may also be provided to increase the capability and efficiency of the battery.

Examples of printed circuit boards integrate several components, including current-limiting resistors for LEDs, a battery management system for safe charging and power regulation, and a driver circuit to ensure consistent LED performance.

Examples of electronic component layouts includes the IR LED emitters positioned at the top of the front of the frame and each IR LED angled to provide coverage of the face and having a 120-degree beam angle; a battery embedded in a frame arm with wiring routed through the frame arm hinge area; a PCB, located in the frame arm, and connecting the LEDs, battery and USB-C port; the USB-C port positioned on the underside of a frame arm for discreet recharging; and a micro-switch located on the inner frame arm for easy access.

In examples of eyeglasses frames embodiments, the component layout will include (a) IR LED emitters positioned on the top of the front of the eyeglasses frame for advantageous facial coverage, (b) one or more batteries discreetly embedded within the frame arm to balance weight distribution, (c) a PCB (Printed Circuit Board) power controller located within an arm of the frame, handling LED control and power distribution, (d) provisions for heat dissipation, including vents in the arms and micro-perforations in the frame to enhance airflow, (e) a micro-switch concealed within one of the frame arms and used for user activation, (f) a USB-C port hidden under or otherwise in a frame arm for easy, discreet charging, and (g) temperature regulation sensors that monitor LED heat output and work with other components to adjust power accordingly.

An example of organization of the components is [Battery]-->[PCB]-->[Switch]-->[LED Driver]-->[Infrared LEDs]-->[Temperature Regulation Sensors].

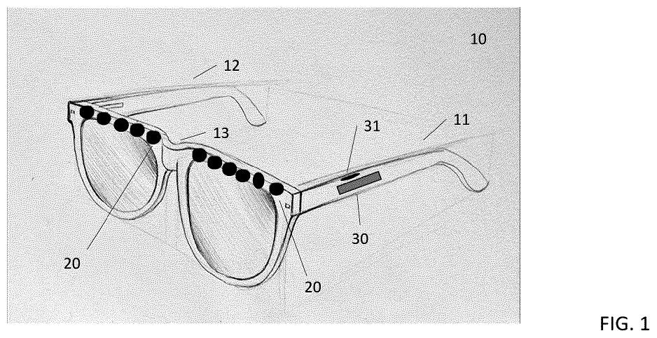

FIG. 1 is a perspective front side view of a schematic of an embodiment of an eyeglasses frame of this invention. It shows an example of the eyeglasses frame 10 and examples of the placement of rows IR LED emitters 20, a battery 30, and a charging port 31. The eyeglasses frame has a left-side arm 11 that is worn near a wearer's left-side temple, a right-side 12 arm that is worn near a wearer's right-side temple, and a center bridge 13. This figure is illustrative only, different IR LED emitters, controllers, other components, other arrangements and ports, etc., may be used.

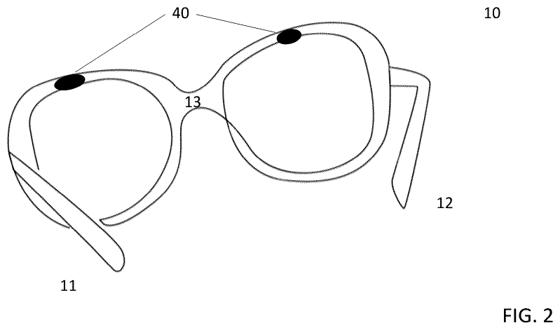

FIG. 2 is a perspective back side view of a schematic of an embodiment of an eyeglasses frame of this invention. It shows an example of the eyeglasses frame 10 and examples of the placement of ventilation slots 40. The eyeglasses frame has a left-side arm 11 that is worn near a wearer's left-side temple, a right-side 12 arm that is worn near a wearer's right-side temple, and a center bridge 13. This figure is illustrative only, different IR LED emitters, controllers, other components, other arrangements and ports, etc., may be used.

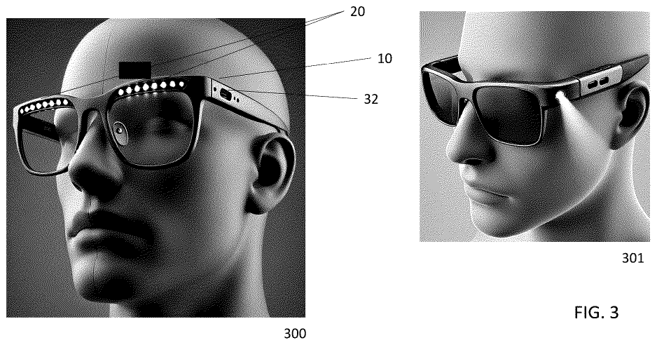

FIG. 3 includes two perspective front side views of drawings of two embodiments of eyeglasses frames of this invention on a wearer's head. The left side 300 shows two rows of IR LED emitters 20 and a power on (or on/off button) 32 on a frame. The right side 301 shows an IR LED emitter on the side of a frame. Another IR LED (not shown) is on the other side of the frame. Different wavelength IR LED emitters can also be used in either embodiment. This figure is illustrative only, different IR LED emitters, controllers, other components, other arrangements and ports, etc., may be used.

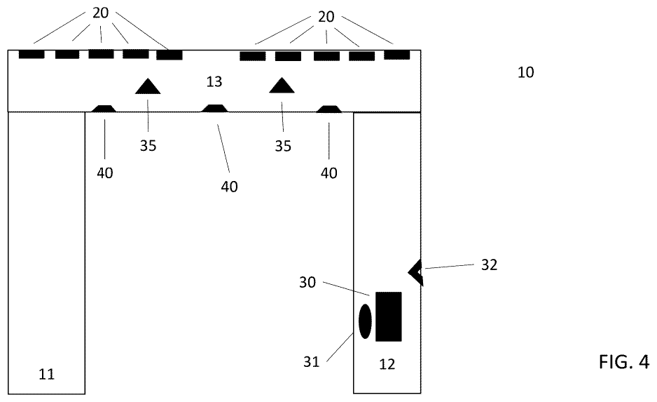

FIG. 4 is a schematic diagram showing the placement of certain components of this invention in an eyeglasses frame 10. It shows examples of the placement of rows of IR LED emitters 20, temperature sensors 35, ventilation slots 40, a battery 30, a charging port 31 and a micro-switch port. The eyeglasses frame has a left-side arm 11 that is worn near a wearer's left-side temple, a right-side 12 arm that is worn near a wearer's right-side temple, and a center bridge 13. This figure is illustrative only, different IR LED emitters, controllers, other components, other arrangements and ports, etc., may be used.

In following the teaching set forth herein, in certain embodiments a general system architecture can be applied that comprises: a power source→control circuit→ambient sensor→IR driver circuit→IR LEDs→frame vent system. This can also comprise IR LEDs with the same or different wavelength emissions, current control, and/or duty cycle modulation. The IR emitter wavelength range in certain embodiments can be comprised of emissions between about 850 nanometers and about 1100 nanometers; with an average radiant intensity per LED measured in mW/sr that is determined to be effective in the particular application (e.g., acceptable disruption); a total array output, such as total irradiance at 0.5 m, 1 m, 2 m, etc., in W/cm², that is determined to be effective in the particular application; an ambient control response (e.g., LED output vs. lux input) that is determined to be effective in the particular application; and/or an effective duty cycle (e.g., a variable 10-100% duty cycle based on ambient conditions).

Thermal management data can be collected (e.g., frame temperature readings after 30 minutes at peak output (e.g., that show a minimal rise)) to enable effective heat dissipation design (e.g., venting layout, materials, air gap dimensions) and confirmation that operation is within skin-contact safety limits. Eye safety verification can also be applied to confirm compliance with IEC 62471 and ISO 15004 exposure limits; provide calculated Maximum Permissible Exposure (MPE) and demonstrate the system remains below it at all operating levels; and/or include third-party verification data or simulation results. Functional test evidence can be collected also (e.g., photo/video test results that show, for example, camera sensor flare out, facial-recognition failure, and/or depth-map corruption) that can document test conditions (e.g., distance, lighting lux, camera type, angle) and show detection confidence drop percentages across major camera systems (Apple, Android, Meta, Tesla interior cam, etc.).

In providing embodiments of this invention, a control algorithm can apply with firmware logic comprising input (ambient sensor)→ADC→control loop→PWM current modulation→output (IR LEDs), with the system adapting between indoor, partial sun, and full daylight.

The choice of power system choice can consider the voltage, battery chemistry, expected runtime, and/or recharge method. In some embodiments, this may include a failsafe cutoff or watchdog behavior for overcurrent, overheat, or fault conditions.

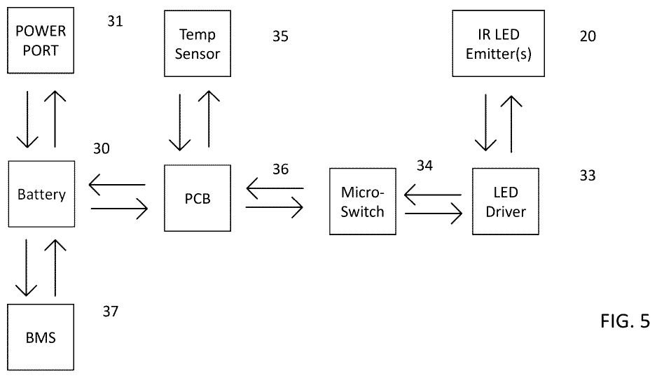

FIG. 5 is a schematic diagram of certain of the connections between examples of components of an embodiment of this invention. It shows an example of the battery 30, battery management system or BMS 37, a port and charger 31, LED driver 33, micro-switch 34, temperature sensor 35, PCB power controller 36, and IR LED emitters 20. A PWM module may be integrated into this diagram (e.g., as part of a PCB 36, LED Driver 33, or as a separate component or incorporated into another component) to provide adaptive logic with a thermal sensor feedback loop. This figure is illustrative only, different IR LED emitters, controllers, other components, other arrangements and ports, etc., may be used.

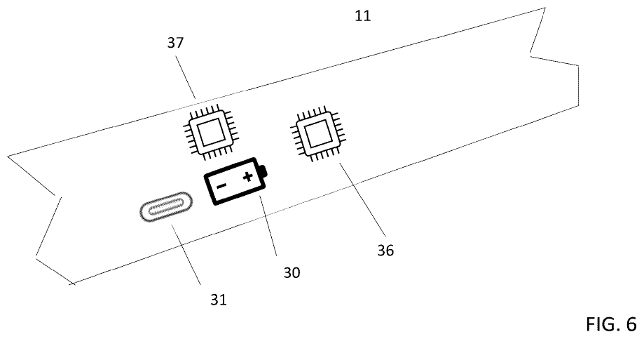

FIG. 6 is an exploded view of a schematic of a portion of the interior of a left-side eyeglasses frame arm 11, illustrating certain of the internal components of an embodiment of this invention, showing the integration of a PCB power controller 36, a battery 30, a BMS or battery management system 37, and a charging port 31. This figure is illustrative only, different IR LED emitters, controllers, other components, other arrangements and ports, etc., may be used.

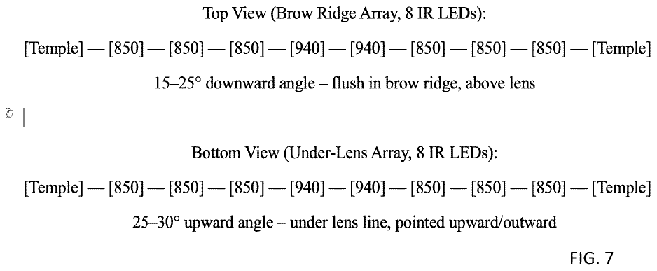

FIG. 7 is a diagram showing IR LED placement in an embodiment of eyeglasses frames of this invention. This figure is illustrative only, different IR LED emitters, controllers, other components, other arrangements and ports, etc., may be used.

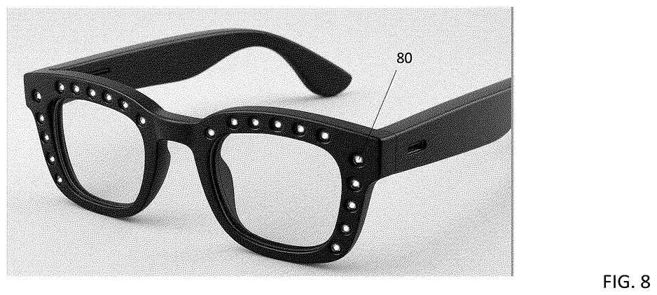

FIG. 8 is a front side view of an embodiment of an eyeglasses frames with IR LED emitters 80 arranged on the top and the outside side of the frames. Different wavelength IR LED emitters s can also be used. This figure is illustrative only, different IR LED emitters, controllers, other components, other arrangements and ports, etc., may be used.

In certain embodiments, eyeglasses frames for a user are provided that disrupt facial landmark detection of the user's face by a facial recognition system. The eyeglasses frames comprise: (a) multiple IR LED emitters, each IR LED emitters embedded into the eyeglasses frame and capable of emitting IR light around the user's face; (b) a power source for providing power to each of the IR LED emitters, the power source comprising multiple power source components that work in concert. The power source components comprise: (i) a high-capacity rechargeable lithium battery, which battery is integrated within the eyeglasses frame, and which battery provides power that is used by each of the IR LED emitters; (ii) a USB-C charging interface, which charging interface is positioned within the eyeglasses frame, and which charging interface charges the battery; (iii) a battery management system, which battery management system is integrated within the eyeglasses frame and is connected to the battery, and which battery management system works with other power source components to regulate power distribution, intensity of each of the IR LED emitters, and heat dissipation; (iv) multiple heat dissipators, the dissipators comprising ventilation slots and micro-perforations in the eyeglasses frame that dissipate heat to prevent overheating of each of the IR LED emitters; (v) temperature regulation sensors, which sensors are embedded in the eyeglasses frame, and which sensors work with other power source components to adjust the output of each of the IR LED emitters based on temperature to prevent overheating of each of the IR LED emitters; (vi) a dynamic power controller that works with other power source components to adjust the intensity of each of the IR LED emitters to maximize facial recognition disruption while preserving battery life; and (vii) an electrical circuit connecting the battery, charging interface, battery management system, sensors, and each of the IR LED emitters.

The eyeglasses frames of these embodiments also comprises: (c) wherein the multiple IR LED emitters disrupt the facial landmark detection by the facial recognition system under various light conditions. The eyeglasses frames perform disruption in a discreet manner. By discreet, it is meant the eyeglassed frames do not immediately look to a casual viewer or passerby like a facial recognition system disrupter but instead looks like a normal pair of glasses that are not out of the ordinary.

In addition, the eyeglasses frames of these embodiments may further comprise a battery that is a lithium-ion or lithium-polymer battery with a capacity of about 300 mAh to about 500 mAh, a voltage of about 3.7V, and is about 4 mm to about 6 mm thick and about 40 mm in length, and/or wherein the battery management system further provides; (a) overcharge protection to ensure safe recharging; and (b) an automatic shut-off of each of the IR LED emitters when they are inactive to save power. In some of these embodiments, the battery management system and the dynamic power controller are provided on a single printed circuit board. In some of these embodiments, the power source further comprises a voltage regulator that maintains a steady approximately 3.7V output for each of the IR LED emitters, and in some embodiments, the power source further comprises current-limiting resistors that prevent excess power draw from each of the IR LED emitters.

In some of these embodiments, the power source further comprises pulse modulation control that provides pulsing IR LED operation to reduce continuous power drain and extend battery life. In some of these embodiments, the power source further comprises a power-saving mode that limits the intensity and/or duration of IR LED use to extend battery life. In some of these embodiments, each IR LED emits at about a 800 nm to about a 950 nm wavelength, or in some at about a 850 nm wavelength or about a 940 nm wavelength. In some of these embodiments, each IR LED emits at about a 120-degree beam angle. In some of these embodiments, some or all of the IR LED emitters emit in a non-repeating sequence to avoid prediction, mapping or adaptation by the facial recognition system.

In other examples of embodiments, methods of disrupting facial landmark detection by a facial recognition system are provided. The methods comprise: (a) wearing eyeglasses frames comprising a power source that can be powered on to provide power to infrared light sources embedded in the eyeglasses frame; (b) powering on the eyeglasses frames to provide the power to the infrared light sources from the power source; (c) providing infrared light from infrared light sources towards the facial landmark detection by the facial recognition system; (d) disrupting the facial landmark detection by the facial recognition system using the infrared light from the infrared light sources.

In these methods, (i) the infrared light sources comprise multiple IR LED emitters, each IR LED emitters embedded into the eyeglasses frames; (ii) the power source for providing power to each of the IR LED emitters, the power source comprising multiple power source components that work in concert, the power source components comprising: (a) a high-capacity rechargeable lithium battery, which battery is integrated within the eyeglasses frame, and which battery provides power that is used by each of the IR LED emitters; (b) a USB-C charging interface, which charging interface is positioned within the eyeglasses frames, and which charging interface charges the battery; (c) a battery management system, which battery management system is integrated within the eyeglasses frames and is connected to the battery, and which battery management system works with other power source components to regulate power distribution, intensity of each of the IR LED emitters, and heat dissipation; (d) multiple heat dissipators, the dissipators comprising ventilation slots and micro-perforations in the eyeglasses frames that dissipate heat to prevent overheating of each of the IR LED emitters; (e) temperature regulation sensors, which sensors are embedded in the eyeglasses frames, and which sensors work with other power source components to adjust the output of each of the IR LED emitters based on temperature to prevent overheating of each of the IR LED emitters; (f) a dynamic power controller that work with other power source components to adjust the intensity of each of the IR LED emitters to maximize facial recognition disruption while preserving battery life; and (g) an electrical circuit connecting the battery, charging interface, battery management system, sensors, and each of the IR LED emitters.

In some of these methods, the battery is a lithium-ion or lithium-polymer battery with a capacity of about 300 mAh to about 500 mAh, a voltage of about 3.7V, and is about 4 mm to about 6 mm thick and about 40 mm in length. In some of these methods the battery management system further provides; (a) overcharge protection to ensure safe recharging; and (b) an automatic shut-off of each of the IR LED emitters when they are inactive to save power. In some of these methods, the battery management system and the dynamic power controller are provided on a single printed circuit board. In some of these methods, the power source further comprises a voltage regulator that maintains a steady approximately 3.7V output for each of the IR LED emitters.

In some of these methods, the power source further comprises current-limiting resistors that prevent excess power draw from each of the IR LED emitters. In some of these methods, the power source further comprises pulse modulation control that provides pulsing IR LED operation to reduce continuous power drain and extend battery life. In some of these methods, the power source further comprises a power-saving mode that limits the intensity and/or duration of IR LED use to extend battery life. In some of these methods, each IR LED emits at about a 800 nm to about a 950 nm wavelength, and in some of these methods each IR LED emits at about a 850 nm wavelength or at about a 940 nm wavelength. In some of these methods, each IR LED emits at about a 120-degree beam angle. In some of these methods, each IR LED emits in a non-repeating sequence to avoid prediction, mapping or adaptation by the facial recognition system.

In still other examples of methods of this invention, methods are provided for avoiding the identification of a person's face by a facial recognition system. These methods comprise: (a) providing pulses of infrared light around a person's face using eyeglasses frames, the eyeglasses frames comprising: (i) multiple IR LED emitters, each IR LED emitters embedded into the eyeglasses frames; (ii) a power source for providing power to each of the IR LED emitters, the power source comprising multiple power source components that work in concert, the power source components comprising: (1) a high-capacity rechargeable lithium battery, which battery is integrated within the eyeglasses frame, and which battery provides power that is used by each of the IR LED emitters; (2) a USB-C charging interface, which charging interface is positioned within the eyeglasses frames, and which charging interface charges the battery; (3) a battery management system, which battery management system is integrated within the eyeglasses frames and is connected to the battery, and which battery management system works with other power source components to regulate power distribution, intensity of each of the IR LED emitters, and heat dissipation; (4) multiple heat dissipators, the dissipators comprising ventilation slots and micro-perforations in the eyeglasses frames that dissipate heat to prevent overheating of each of the IR LED emitters; (5) temperature regulation sensors, which sensors are embedded in the eyeglasses frames, and which sensors work with other power source components to adjust the output of each of the IR LED emitters based on temperature to prevent overheating of each of the IR LED emitters; (6) a dynamic power controller that work with other power source components to adjust the intensity of each of the IR LED emitters to maximize facial recognition disruption while preserving battery life; and (7) an electrical circuit connecting the battery, charging interface, battery management system, sensors, and each of the IR LED emitters.

These other methods further comprise: (b) disrupting the image of the person's face captured by the facial recognition system with the pulses of infrared light so that the facial recognition system fails to identify the person's face.

In some of these other methods, the battery is a lithium-ion or lithium-polymer battery with a capacity of about 300 mAh to about 500 mAh, a voltage of about 3.7V, and is about 4 mm to about 6 mm thick and about 40 mm in length. In some of these other methods, the battery management system further provides; (a) overcharge protection to ensure safe recharging; and (b) an automatic shut-off of each of the IR LED emitters when they are inactive to save power. In some of these other methods, the battery management system and the dynamic power controller are provided on a single printed circuit board. In some of these other methods, the power source further comprises a voltage regulator that maintains a steady approximately 3.7V output for each of the IR LED emitters. In some of these other methods, the power source further comprises current-limiting resistors that prevent excess power draw from each of the IR LED emitters. In some of these other methods, the power source further comprises pulse modulation control that provides pulsing IR LED operation to reduce continuous power drain and extend battery life. In some of these other methods, the power source further comprises a power-saving mode that limits the intensity and/or duration of IR LED use to extend battery life.

In some of these other methods, each IR LED emits at about a 800 nm to about a 950 nm wavelength and in some of these other methods each IR LED emits at about a 850 nm wavelength or a 940 nm wavelength. In some of these other methods, each IR LED emits at about a 120-degree beam angle. In some of these other methods, each IR LED emits in a non-repeating sequence to avoid prediction, mapping or adaptation by the facial recognition system.

The subject matter of this disclosure is now described with reference to the following examples. These examples are provided for the purpose of illustration only, and the subject matter is not limited to these examples, but rather encompasses all variations which are evident as a result of the teaching provided herein.

### Example 1

This example describes certain of the components, capabilities and features of certain of the examples of embodiments of this invention. These include:

1. Eyeglasses frames (e.g., prescription-compatible frames) with embedded infrared disrupters that are multiple high-powered IR LED emitters, each emitting at a disrupting (e.g., 850 nm, 940 nm or other) wavelength and with a 120-degree beam angle, arranged in a multi-point emission system, and positioned along the top of the front of the frames to disrupt facial landmark detection.

3. A stealth design, wherein the infrared components are fully flush-mounted, ensuring the eyeglasses appear like conventional eyewear. The frame may have a matte black finish for aesthetic discretion.

4. One or more heat dissipators embedded in the frames that are ventilation slots and/or micro-perforations integrated in the eyeglasses frames for cooling the infrared disrupters (i.e., IR LED emitters) without affecting aesthetics.

5. Temperature regulation sensors embedded in the frames that monitor and adjust IR LED output based on the temperature, and working with other related components. In addition, the frame is constructed from heat-resistant, thermally conductive polymer for durability and comfort.

6. An embedded power source that includes a high-capacity rechargeable 3.7V lithium-ion (or lithium-pulse) battery of 300 mAh-500 mAh that is ultra-thin and flexible, a concealed USB-C charging interface that is used to recharge the battery, a hidden micro-switch for activation, and a power controller (e.g., LED driver) that provides power to the infrared disrupters (i.e., the IR LED emitters). The power distribution to the IR LED emitters may also include a voltage regulator that maintains a steady 3.7 output for consistent IR LED brightness, current-limiting resistors that prevent excess power draw from IR LED emitters, and/or pulse modulation control wherein the pulsing IR LED operation reduces continuous power drain and extends battery life.

The power cables for these components can be discreetly routed through the frame hinges from the arms to the top of the front of the frames where the IR LED emitters are positioned. A microcontroller can be used to regulate the IR LED emitters intensity dynamically, and a compact BMS board (see below) can be used to protect against overcharging and heat issues.

7. A Battery Management System (BMS) that regulates power distribution, IR LED intensity, heat dissipation, and works with other related components. It may include a smart power controller that dynamically adjusts IR LED intensity to conserve battery life, overcharge protection to ensure safe recharging via the USB-C charging interface, thermal sensors that monitor temperature and regulate power to prevent overheating, and/or an auto-shutoff feature when the IR LED emitters are inactive to save power. The eyeglasses frames in some embodiments have a the battery management system that comprises an automatic shut-off when the eyeglasses frames are not in use and a passive mode for power conservation that does not degrade the disruptive capability of the eyeglasses frames.

8. Wearable and ergonomic for a sufficient amount of time (e.g., for about 3 hours or longer) using a lightweight, durable frame design for extended wear with prescription or non-prescription lenses.

9. Multi-environment functionality that is effective in low-light conditions and daylight, leveraging high-powered IR emissions to interfere with camera sensors.

10. Automated power management using a self-regulating and dynamic power controller that automatically adjusts IR intensity and heat dissipation dynamically as conditions of duration and use change and which maximizes facial recognition disruption while preserving battery life.

### Example 2

Methods of using the components, capabilities and features of these examples of embodiments of Example 1 to interfere with facial recognition systems include wearing the eyeglasses frames, turning them on so that the infrared disrupter is operational, and facing or otherwise being exposed to a facial recognition system, wherein the facial recognition system is defeated and cannot identify the wearer of the eyeglasses frames.

### Example 3

In this example, the anti-facial recognition eyeglasses incorporate a total of 16 IR LED emitters (near-IR emitters) flush-mounted inside a custom eyeglass frame. The IR LED layout consists of two horizontal arrays of LEDs concealed along the frame—an upper brow ridge array and a lower under-lens array—designed to be virtually invisible to onlookers yet highly effective against IR-sensitive cameras. Twelve LEDs (e.g., 850 nm, 940 nm and/or other) and four additional LEDs (e.g., 850 nm, 940 nm and/or other) are strategically distributed to maximize infrared output while minimizing visible signature. The emitters are internally recessed (i.e., discreet), so there is no external visibility or glow from the frame during operation (e.g., in some embodiments 850 nm diodes provide a faint red output that is hidden, and 940 nm diodes that are inherently covert). This stealth configuration allows the glasses to appear ordinary to the human eye, while actively confounding facial recognition systems that rely on IR illumination.

Each row of IR LED emitters contains 8 IR LED emitters mounted from temple to temple along the frame's inner rim. The top row of 8 LEDs is embedded in the brow portion of the frame, just above the lenses. These top-row LEDs are angled downward by 15-25° toward the wearer's face. This downward tilt focuses IR light onto the upper face (eyes and nose region) and forward toward cameras below the eye-line. The bottom row of 8 LEDs is mounted just under the lenses, along the lower frame interior, and angled upward by 25-30° (and slightly outward) to illuminate the lower face (nose, mouth, chin) and upward toward cameras above the eye-line. This dual-row angular placement creates an overlapping 120° vertical arc of coverage (approximately)—effectively flooding the entire face with IR light from both above and below. By covering a wide vertical span, the system eliminates any dark shadows under the brow, nose, or jaw that IR cameras could use to discern 3D facial contours. Both LED rows sit flush with the frame's inner surface, preserving a sleek appearance and ensuring no protrusion or visible LED elements externally.

To achieve a balance between IR power and stealth, the layout in this particular embodiment uses 850 nm LEDs at the outer zones of the frame and 940 nm LEDs at the central zones. The higher-output 850 nm emitters are positioned toward the left and right edges of each row (near the temples) where maximum IR intensity (“punch”) is needed for wide-angle coverage. The central emitters (near the midpoint of the glasses, around the nose bridge area) are the 940 nm type, which are “covert IR” LEDs producing no visible red glow—ideal for stealth directly in front of the wearer's eyes. This zoning ensures that the visible parts of the array (center of the face) use fully invisible IR, while the peripheral units provide additional IR illumination strength (850 nm LEDs, which cameras are most sensitive to). All 16 LEDs combined provide approximately a 180° horizontal field of IR illumination coverage, blanketing the wearer's face in IR light from ear to ear. This broad, diffuse IR flood overwhelms the imaging sensors of infrared cameras, effectively obscuring facial features. By emitting in the near-infrared spectrum beyond human vision (~740 nm and up), the glasses blind or oversaturate IR-sensitive cameras without any visible distraction to the wearer or others. The result is a full-face IR glow (captured by surveillance cameras) that washes out distinguishable landmarks, preventing reliable face detection or 3D mapping. Importantly, the arrangement is calibrated such that no single point on the face is under-lit—the multi-angle IR exposure eliminates characteristic shadows and flattens the appearance of facial geometry under IR, defeating recognition algorithms. Other combinations of different IR LEDs can be used.

FIG. 7 shows a layout diagram of the IR LED placement in the eyeglasses frames of this example. Sixteen IR LED's are used, eight on the top of the frames (flush in the brow ridge and above the lenses) and eight on the bottom of the frames (under the lens).

Each “[850]” in FIG. 7 denotes a high-output 850 nm IR LED; each “[940]” in FIG. 7 denotes a covert 940 nm IR LED. Outer-zone 850 nm LEDs provide strong IR intensity for wide 180° coverage, while the central 940 nm LEDs ensure no visible light emission in the critical front-central field. All diodes are concealed inside the frame thickness, with their emission directed through IR-transparent frame material.

Continuous operation of high-power IR LED emitters can generate significant heat—for example, a typical IR LED can overheat in just a few seconds of constant drive. To prevent thermal buildup while preserving performance, the glasses employ an adaptive thermal modulation system controlled by an onboard microcontroller. The microcontroller actively monitors the temperature of the IR LED diodes (via integrated thermistors or diode junction temperature sensing) and dynamically adjusts the strobe pulse frequency and duty cycle of the LED driving signals. Rather than driving the LEDs in steady-state, the controller drives them in a rapid pulsed IR strobe within a range of approximately 5-20 Hz. This means the IR LED emitters blink on and off faster than the human eye can perceive (infrared being invisible regardless), but fast enough to appear as a near-constant flood to a camera. The duty cycle (the ON vs. OFF time ratio of each pulse) is modulated based on real-time temperature feedback: if the LEDs' temperature approaches a defined threshold, the controller automatically shortens the ON duration or lengthens the OFF interval of pulses to reduce heat accumulation. Conversely, when temperature is within safe limits, the system can use a higher duty cycle (longer pulses) to maximize IR output. This adaptive PWM-based drive ensures the LEDs operate within safe thermal limits at all times, avoiding overheating or damage.

Crucially, the thermal modulation is designed not to compromise the glasses' anti-facial-recognition effectiveness. The microcontroller maintains the strobing within the optimal disruption frequency range of 5-20 Hz, which is fast enough to continuously interfere with camera imaging. At these pulse rates, surveillance camera frames are consistently saturated or disrupted by IR bursts, maintaining the “facial disruption integrity” of the system (i.e., the face remains washed out in IR on the camera feed). In essence, the LED driver circuitry controls the IR light output and strobes it at an appropriate frequency and duty cycle for this application, finding a balance between maximum optical output and thermal safety.

The adaptive logic leverages PWM thermal management techniques: temperature sensors feed into a control loop that adjusts LED PWM duty cycle to counteract any rise in junction temperature. By reducing the duty cycle when the LEDs get too warm, the system lowers the average power dissipation (allowing the diodes to cool) while still emitting periodic IR flashes. This approach improves the stability and reliability of the IR emitters under all conditions, effectively extending LED lifespan and preventing performance degradation. In summary, the adaptive thermal modulation ensures that the anti-recognition glasses deliver a consistent, effective IR output for facial masking, without overheating, through intelligent real-time adjustment of strobe frequency and duty cycle based on LED temperature. This guarantees that the device remains safe and functional over prolonged use, all while maintaining its full disruptive capability against facial recognition systems.

### Example 4

FIG. 8 shows another embodiment of an array of IR LED emitters on the front of eyeglasses frames. One of the IR LED emitters is identified as 80. This array is across the top of the front of the frames and the sides of the front of the frames. It should be understood that the IR LED emitters can be placed anywhere on the frames, in any number, as long as disruption of facial recognition systems is achieved.

### Example 5

In these embodiments, the eyeglasses frames with disruptive IR LED emitters are worn or positioned within proximity to the face and the frames function independently of, or as part of, a larger biometric defense system, including but not limited to the frames used with other IR disruptive devices that may include facewear, headgear, jewelry, smart accessories (e.g., mobile phones), and/or handheld form factors (e.g., devices comprising computer components), among other types of devices.

In certain of these embodiments, protection against biometric data harvesting beyond facial recognition is also provided. This may include disruption of eye-tracking, gaze analysis, 3D depth mapping, iris scans, and/or other biometric data collection techniques. In some of these embodiments, the device is configured to interfere with, obstruct, and/or degrade acquisition of biometric data including but not limited to facial recognition, gaze tracking, iris scanning, 3D depth mapping, and/or photoplethysmography.

In other embodiments, the eyeglasses frames with disruptive IR LED emitters are worn and used with additional IR emitter modules that attach to other hardware that may include detachable modules, clip-on emitter systems, and/or integration into existing smartglass products.

### Example 6

In these embodiments, the eyeglasses frames with IR LED emitters are configured to emit IR in a manner that disables, corrupts, or saturates the raw sensor input of imaging systems, such that no post-processing, image correction, AI inference, or machine learning model can restore facial feature data to a recognizable state.

### Example 7

In these embodiments, the IR LED emitters are in the form of arrays and are placed on the side of the eyeglasses frames. In other embodiments, the IR LED emitters are placed to provide full, wrap-around 360 degree coverage of the wearers head. In this latter embodiment, the eyeglasses frames may require extensions of the frame arms to cover the back of the head. By different placement of IR LED emitters on the devices used, 360 degree (or less) coverage of the face, top of head, sides of head, and entire head, as well as other parts of the body, can be achieved with embodiments of this invention. This can be achieved in approximately 2 dimensional planes or 3 dimensional spheres of IR coverage.

### Example 8

In these embodiments, the emission pattern of the IR LED emitters is randomized and/or dynamically modulated in real time via onboard artificial intelligence (“AI”) and/or sensor feedback, to prevent adaptation by camera-based or AI-driven facial recognition systems. This provides coverage for random, dynamic, and/or AI-controlled IR emission patterns and prevents circumvention through predictable pulsing or timing attacks.

In certain of these embodiments, all or only some (a subset) of the IR LED emitters are activated to obtain disruption. This can include targeted IR LED emitters to certain areas and/or targeted IR LED emitters of certain wavelengths and/or angles. This may obtain minimized power consumption and/or a variable emission signature that may enhance the ability to avoid a facial recognition system defeating the disruption caused by the eyeglasses frames.

### Example 9

In these embodiments, the eyeglasses frames have IR LED emitters that maintain facial recognition disruption in varying lighting conditions, including direct sunlight, low-light, infrared-rich, or infrared-poor (e.g., low-infrared containing, such as an environment with no or low amounts of natural sunlight (e.g., indoors without windows or windows with low-e coatings)) environments.

### Example 10

In these embodiments, the eyeglasses frames further comprise a camera detection subsystem integrated (e.g., embedded with connections to power source components) into the frames and the power source components. The subsystem automatically activates the IR disruption system of the frames upon detection of an imaging sensor, lens reflection, infrared focus mechanism, location known to have a camera, and/or other indication a camera is in proximity. This can be provided by integration of camera detection sensors on the frames and permitting proximity-based activation. It may prevent circumvention by activating the device only when under surveillance.

### Example 11

In these embodiments, the eyeglasses frames are effective against several types of detection/recognition systems, such as those in vehicle dashcams, drones, and/or automated public imaging systems, among others, and are not limited to person-to-camera interactions. In these embodiments, the IR disruption system of this invention is operable during exposure to stationary, mobile, and/or airborne imaging systems, including but not limited to dashcams, drones, surveillance towers, and/or automated biometric kiosks, among others.

### Example 12

In certain embodiments of this invention, temperature control systems are used, such as a thermal feedback control loop with Pulse Width Modulation (PWM). These are systems that use temperature measurements to adjust the power that is being delivered to, for example, a cooling system (e.g., fan). Instead of a simple on/off switch, PWM rapidly cycles the power, varying the on-time (duty cycle) to provide a precise, time-averaged power level. These methods are often more efficient and accurate than on/off control, as it may prevent large temperature swings and power spikes.

Such a PWM thermal feedback control loop can be incorporated in a PCB (e.g., FIG. 5, 36) and/or an LED Driver (FIG. 5, 33), with input from a Temp Sensor (e.g., FIG. 5, 35), or as a separate component or incorporated into other components, as examples.

A exemplary PWM thermal feedback control loop is comprised of four main parts: (1) a sensor or connection to such (e.g., a temperature-sensitive component, such as a thermistor or thermocouple, measures the current temperature of the system or component); (2) a controller (e.g., often a microcontroller (like an Arduino) or a dedicated PID controller chip, which has the job of calculating the difference (error) between the measured temperature and the desired setpoint temperature); (3) an actuator or connection to such (e.g., an element that is controlled by the PWM signal, which could be a solid-state relay for a cooling element, a fan motor, or a thermoelectric cooler, among other devices); and (4) a PWM generator (e.g., a feature of the controller that creates a square-wave output signal, wherein the duty cycle of this signal is adjusted by the controller to manage the average power sent to the actuator).

An exemplary PWM thermal feedback control loop process is a continuous cycle of sensing, calculating, and adjusting. For example, these steps can comprise sensing (e.g., a temperature sensor measures the current temperature); comparison (e.g., a controller compares the current temperature to the user (person, software, AI)-defined setpoint temperature); error calculation (e.g., the controller calculates the error as the difference between the current and defined setpoint temperature); control action (e.g., using the error value, a control algorithm—such as Proportional-Integral-Derivative (PID) algorithm-determines the necessary adjustment); PWM adjustment (e.g., the algorithm's output is used to set the PWM duty cycle, wherein a larger error (e.g., the system is much hotter than the setpoint) results in a longer “on” time for the PWM signal, sending more power to the cooling element); actuation (e.g., the PWM signal drives the cooling element, delivering an averaged power that adjusts the system's temperature); and looping (e.g., the temperature sensor immediately detects the change, and the process repeats, constantly correcting for any drift from the setpoint).

The use of such PWM thermal control in certain embodiments may provide some advantages, such as: increased efficiency (e.g., unlike on/off control, which can cause large energy spikes, PWM may deliver only the necessary average power, reducing wasted energy); greater accuracy (e.g., by constantly and proportionally adjusting power, PWM can maintain temperatures with a much higher degree of precision than a simple on/off switch); reduced noise and wear (e.g., for cooling fans, PWM control allows the fan speed to be adjusted based on the thermal load, and the fans run quieter when the system is cool and increase speed only when necessary, which also prolongs the life of the motor); and/or smoother control (e.g., thermal systems often have a large thermal mass and react slowly to changes, while the rapid PWM switching happens much faster than the system's thermal response, allowing for a smooth and stable average power delivery that prevents overshooting or undershooting the target temperature).

### Example 13

In these embodiments, a backup or alternative power source (“auxiliary power source”) is provided for the device (e.g., embedded in the device and connected to the power source components). Certain of these embodiments use an emergency capacitor and/or have a dual-power design with another power source (e.g., a second battery of a smaller, larger or the same size). This auxiliary power source in some embodiments is configured to provide short-duration IR output during main battery failure and/or system interruption. In some embodiments, the eyeglasses frames also contain embedded within them an auxiliary power source that is used to provide power to the IR LED emitters if a main or principal power source is not operational.

### Example 14

This example is directed to several of the examples of embodiments that comprise eyeglasses frames for a user to wear and methods for using them.

The eyeglasses frames are capable of disrupting a facial recognition system that uses facial landmark detection of the user's face. These eyeglasses frames comprise: (a) multiple IR LED emitters, each of the IR LED emitters attached (e.g., embedded within) to the eyeglasses frames and capable of emitting IR light near (e.g., in the proximity) of the user; and a (b) a power source for providing power to each of the IR LED emitters, the power source comprising multiple power source components that work in concert.

The power source components comprise: (i) a high-capacity rechargeable lithium battery, said battery being integrated within the eyeglasses frames, and said battery providing power that is used by each of the IR LED emitters; (ii) a USB-C charging interface, said charging interface being positioned within the eyeglasses frames, and said charging interface charging the battery; (iii) a battery management system, said battery management system being integrated within the eyeglasses frames and being connected to the battery, said battery management system working with other power source components to regulate power distribution, intensity of each of the IR LED emitters, and heat dissipation; (iv) multiple heat dissipators, said heat dissipators comprising ventilation slots and/or micro-perforations in the eyeglasses frames that dissipate heat to prevent overheating of each of the IR LED emitters; (v) temperature regulation sensors, said sensors being embedded in the eyeglasses frames, and said sensors working with other power source components to adjust the output of each of the IR LED emitters based on temperature to prevent overheating of each of the IR LED emitters; (vi) a dynamic power controller, said power controller working with other power source components to adjust the intensity of each of the IR LED emitters to maximize the disruption of the facial recognition system and preserving battery life; and (vii) an electrical circuit connecting the battery, the charging interface, the battery management system, the sensors, and each of the IR LED emitters.

In these embodiments, when activated, some or all of the multiple IR LED emitters disrupt the facial recognition system under various light conditions, and the eyeglasses frames are discreet and comfortably wearable for at least three hours at a time.

Selections of the examples of components and capabilities include each of the following, taken individually: (1) wherein the battery is a lithium-ion or lithium-polymer battery with a capacity of about 300 mAh to about 500 mAh, a voltage of about 3.7V, and is about 4 mm to about 6 mm thick and about 40 mm in length; (2) wherein the battery management system further provides (a) overcharge protection to ensure safe recharging of the battery and (b) an automatic shut-off of each of the IR LED emitters when they are inactive to save power; (3) wherein the battery management system further comprises an automatic shut-off when the eyeglasses frames are not in use and a passive mode for power conservation that does not degrade the disruptive capability of the eyeglasses frames; (4) wherein the battery management system and the dynamic power controller are provided on a single printed circuit board; (5) wherein the power source components further comprise a pulse width modulation thermal feedback control loop; (6) wherein the power source further comprises a voltage regulator that maintains a steady approximately 3.7V output for each of the IR LED emitters; (7) wherein the power source further comprises current-limiting resistors that prevent excess power draw from each of the IR LED emitters; (8) wherein the power source further comprises pulse width modulation control that provides pulsing IR LED operation to reduce continuous power drain and extend battery life; (9) wherein the power source further comprises a power-saving mode that limits the intensity and/or duration of IR LED use to extend battery life; (10) wherein each IR LED emits at a wavelength from about 780 nm to about 1100 nm wavelength; (11) wherein each IR LED emits at a wavelength from about 850 nm to about 940 nm wavelength; (12) wherein each IR LED emits at about a 120-degree beam angle; and/or (13) wherein each IR LED emits in a non-repeating sequence to avoid prediction, mapping, and/or adaptation by the facial recognition system.

Additional selections of the examples of components and capabilities also include the following, each taken individually: (14) wherein the emission pattern of the IR LED emitters is randomized and/or dynamically modulated in real time via onboard artificial intelligence (“AI”) and/or sensor feedback, to prevent adaptation by a camera-based and/or AI-driven facial recognition system; (15) wherein the eyeglasses frames are used with other IR disrupter devices, the other IR disrupter devices comprising face ware, headgear, jewelry, smart accessories, and/or handheld form factors; (16) wherein the eyeglasses frames are used with IR emitter modules comprising one or more IR LED emitters, wherein said IR emitter modules attach to other hardware, and wherein the other hardware comprises detachable modules, clip-on emitter systems, and/or integration into existing smartglass products; (17) wherein the IR LED emitters are configured to emit IR in a manner that disables, corrupts, and/or saturates the raw sensor input of imaging systems, such that no post-processing, image correction, AI inference, and/or machine learning model can restore facial feature data to a recognizable state; (18) wherein the IR LED emitters are placed on frames to provide 360 degree coverage over at least a portion of the user's head; (19) wherein the power source components further comprise a pulse width modulation controller module that provides adaptive logic with a thermal sensor feedback loop; (20) wherein facial recognition system disruption is maintained in varying ambient lighting conditions, including direct sunlight, low-light, infrared-rich, and/or low-infrared environments; (21) wherein the eyeglasses frames further comprise a camera detection subsystem that automatically activates the IR LED emitters of the frames upon detection of an imaging sensor, lens reflection, and/or infrared focus mechanism; (22) wherein the eyeglasses frames are further configured to interfere with, obstruct, and/or degrade acquisition of biometric data including but not limited to facial recognition, gaze tracking, iris scanning, 3D depth mapping, and/or photoplethysmography; (23) wherein the IR disruption is operable during exposure to stationary, mobile, and/or airborne imaging systems that comprise dashcams, drones, surveillance towers, and/or automated biometric kiosks; (24) wherein the frames comprise thermally conducive, heat-resistant, IR transparent and/or IR diffusing materials; and/or (25) wherein an auxiliary power source is used to provide power to the IR LED emitters if the power source is not operational.

These examples of embodiments and selections can be used in methods of disrupting facial recognition systems, the methods comprising: (1) wearing the eyeglasses frames; (2) powering on the eyeglasses frames to provide the power to some or all of the IR LED emitters; (3) providing infrared light from some or all of the IR LED emitters in the proximity of the wearer; and (4) disrupting the facial recognition systems using the infrared light provided from some or all of the IR LED emitters.

These examples of embodiments and selections also can be used in methods of avoiding the identification of a user's face by facial recognition systems, the methods comprising: (1) providing pulses of infrared light using the eyeglasses frames; and (2) disrupting facial recognition systems with the pulses of infrared light provided by the eyeglasses frames so that facial recognition systems fail to identify the user's face

### Example 15

In these embodiments, eyeglasses frames for disrupting facial recognition of a user's face are provided. They comprise: (a) a plurality of infrared emitters configured to emit near-infrared radiation within about 780-1100 nanometers; (b) a power subsystem operatively coupled to the emitters; (c) at least one controller configured to modulate emission intensity and/or timing, optionally in response to sensor input; (d) thermal-management elements operatively coupled to the emitters; and (e) wherein, when activated, the infrared emission disrupts facial recognition under varied ambient lighting conditions while the frames maintain the appearance of ordinary eyeglasses.

Examples of selections of components and features of these embodiments include: (1) wherein the emitters emit at about 850 nm and/or about 940 nm; (2) wherein the emitters provide a beam spread sufficient to cover facial features; (3) wherein the beam spread is about 120°; (4) wherein the controller implements pulse-width modulation with thermal feedback; (5) wherein activation is triggered by a camera detection subsystem; (6) wherein the disruption extends to iris, gaze, depth, or PPG biometrics; (7) wherein the frames comprise heat-resistant, IR-diffusing polymers; and (8) wherein the frames include an auxiliary power source or capacitor for continued short-term emission on battery failure.

Method embodiments of this example can include a method comprising: wearing the eyeglasses frames of this example; powering on the emitters; and disrupting capture of facial features such that recognition fails. Additional method embodiments can include a method comprising: activating the eyeglasses frames of this example to emit randomized or sensor-responsive infrared patterns; and preventing post processing or artificial intelligence restoration of facial data.

### Example 16

In this example, a wearable eyewear device for disrupting biometric image capture is provided and used in a method for disruption. It comprises a frame configured in an eyewear form factor, the frame comprising a bridge, lens rims, and temple arms; a plurality of infrared emitters embedded in and distributed around said frame, where the plurality of infrared emitters comprises at least sixteen emitters and not more than thirty-two emitters, said emitters being located at the bridge, along lower rim portions adjacent to the cheeks, at frontal portions of the temples, and at rearward portions of the temple arms to provide wrap-around coverage of a wearer's face; each infrared emitter configured to emit light within a spectral band between about 780 nm and about 1100 nm. The device also comprises a controller operatively coupled to the emitters and configured to selectively activate subsets of emitters in randomized or sensor-responsive patterns, including variations in duty cycle, pulse width, and sequence, to prevent machine-learning reconstruction of facial features.

In this example, the eyewear device further comprises a power subsystem operatively coupled to the frame, the power subsystem comprising at least one of: an integrated power source within the frame, or an external power source coupled through a connector at a temple arm (or both), enabling higher sustained output for daylight operation; and a thermal management feature integrated into the frame, including one or more ventilation slots or equivalent structures to dissipate heat generated by the plurality of emitters.

This eyewear device is constructed so that emission of said plurality of emitters disrupts biometric recognition systems including facial recognition algorithms, by obscuring or distorting image capture of the wearer's facial features under varied lighting conditions, including daylight. The emission also further disrupts structured-light and time-of-flight depth sensing systems by introducing non-coherent infrared patterns and saturating depth-mapping sensors, thereby corrupting three-dimensional facial feature reconstruction.

The controller in this example is configured to vary emission timing relative to anticipated rolling-shutter sensor exposures, producing frame-to-frame inconsistencies unrecoverable by temporal averaging algorithms. The controller also adjusts emitter output to maintain disruption across ambient illuminance levels between at least about 200 lux and about 10,000 lux; where at least a subset of said emitters are configured to deliver peak radiant power of at least 5 watts per diode, enabling disruption under direct daylight conditions.

In particular embodiments of this example, the plurality of emitters comprises exactly twenty-four (24) emitters distributed as: five at a bridge region, four along a left lower rim portion adjacent a cheek, four along a right lower rim portion adjacent a cheek, three at a left frontal temple portion, three at a right frontal temple portion, two at a left rear temple arm portion, and two at a right rear temple arm portion, to provide wrap-around facial coverage. In some of these, each infrared emitter is configured to emit principally within about 850 and about 950 nm, and in some of these, the plurality of emitters collectively provides multi-band emission, including a first band centered at about 850 nm and about 880 nm and a second band centered at about 930 nm and about 950 nm, each with a full width at half maximum (FWHM) of ≤40 nm. In still other particular embodiments of this example, the controller is configured to generate pseudo-random activation sequences using a seeded random number generator and to vary duty cycle and pulse width per emitter independently to reduce temporal periodicity detectable by recognition pipelines. In some of these, the controller modulates emitters using pulse-width modulation in a frequency range of about 100 Hz to about 20 kHz, with per-emitter duty cycles between about 10% and about 90% and temporal jitter of +5-15%.

In still other particular embodiments of this example, an ambient light sensor (ALS) having a spectral response spanning about 400 and about 1100 nm is used and the controller is configured to sample the ALS at ≥100 Hz and to switch between a daylight mode and a low-light mode based on measured illuminance thresholds.

In still other particular embodiments of this example, thermal management features comprise vent slots formed in the bridge and temple portions, each slot having a width between about 0.3 mm and about 1.5 mm and a length between about 3 mm and about 10 mm, with an array density of at least four slots per temple. In certain embodiments, a thermally conductive path from at least the temple-mounted emitters to a heat spreader formed of graphite sheet, aluminum, copper, or thermally conductive polymer, is disposed within the temple arm.

In still other particular embodiments of this example, the power subsystem comprises an external power source releasably coupled at a temple connector via a reversible multi-contact interface and a two-conductor shielded or braided cable, the external source providing a nominal output between about 5 and about 12 V. In certain embodiments, the controller regulates emitter current via constant-current drivers with per-channel resolution of ≥8 bits, and monitors pack voltage and current to maintain output within a daylight operating envelope. In certain embodiments, the controller is configured to partition the plurality of emitters into emitter groups comprising at least a bridge group, left cheek group, right cheek group, left temple group, right temple group, left rear group, and right rear group, and to phase-stagger the groups to avoid constructive interference patterns. In some of these embodiments, the bridge-located emitters are tilted downward by about 5 to about 15° relative to a horizontal plane of the frame, cheek-adjacent emitters are tilted upward by about 5 to about 20°, and temple-front emitters are toed-in by about 10 to about 25° toward a sagittal plane of the wearer, thereby increasing coverage across yaw and pitch variation.

In still other particular embodiments of this example, at least a subset of emitters are equipped with integrated optics providing distinct angular dispersions, including wide (≥60° FWHM), intermediate (30-60° FWHM), and narrow (≤30° FWHM) emission.

In still other particular embodiments of this example, the controller is further configured to avoid flicker perceptible to a human by constraining fundamental modulation components to ≥200 Hz while maintaining higher-frequency content sufficient to degrade rolling-shutter sensors. In certain embodiments, the device further comprises a temperature sensor disposed within a temple arm and coupled to the controller, the controller being configured to reduce emitter drive or shut down selected groups upon a sensed temperature exceeding a first threshold and to shut down all emitters upon a second, higher threshold. In some embodiments, at least one sensor comprises a near-infrared photodiode with a bandpass filter centered between about 850 and about 950 nm configured to detect retroreflective glints indicative of camera optics, the controller responsive thereto to prioritize activation of temple-front and bridge groups.

In still other particular embodiments of this example, the eyewear frame comprises matte black, low-gloss exterior surfaces and anti-reflective inner lens coatings to reduce secondary reflections into imaging sensors. In some embodiments, the controller implements a blue-noise or Poisson-disk temporal/spatial distribution of activations so that no emitter group repeats within a fixed window, thereby reducing spatiotemporal regularity. In some embodiments, the controller logs operating mode, emitter group activity, ALS values, and temperature to non-volatile memory for compliance and performance tuning.

In still other particular embodiments of this example, the external power source includes a mechanical latch or magnetic retention to the temple interface to prevent accidental decoupling during operation. In some embodiments, the ALS thresholds and emitter-group schedules are user-configurable via a wired service interface during provisioning and thereafter locked by secure configuration. In some embodiments, the emitter groups are phase-shifted relative to one another by about 15 to about 120 degrees of a base modulation period to minimize coherent bands in captured imagery. In some embodiments, the spectral band is adaptively selected between about 780 nm to about 880 nm, about 880 nm to about 980 nm, and about 980 nm to about 1100 nm based on ambient spectrum or sensor feedback.

In still other particular embodiments of this example, the controller enforces output limits consistent with eye-safety exposure guidelines for near-infrared emission.

### OTHER EMBODIMENTS

Although the present invention has been described with reference to teaching, examples and embodiments, one skilled in the art can easily ascertain its essential characteristics, and without departing from the spirit and scope thereof can make various changes and modifications of the invention to adapt it to various usages and conditions. Those skilled in the art will recognize or be able to ascertain using no more than routine experimentation, many equivalents to the specific embodiments of the invention described herein. Such equivalents are encompassed by the scope of the present invention.

What is claimed is:

1. A wearable privacy-protection system comprising:
(a) an eyeglass frame;
(b) a plurality of infrared light-emitting diodes positioned along the frame and configured to emit within a spectral range of approximately 780 to approximately 1100 nanometers;
(c) at least one ambient-light sensor configured to detect surrounding illumination;
(d) a control circuit and microcontroller configured to modulate the wavelength, intensity, and emission pattern of the infrared light based on ambient light data;
(e) a power source that is independent or detachable that is electrically connected to the control circuit;
(f) a vented frame structure for passive cooling; and
(g) wherein the emitted infrared light interferes with image sensors and biometric recognition systems to prevent unauthorized facial-recognition or depth-mapping of the wearer while maintaining compliance with applicable eye-safety standards.

2. A wearable eyewear device for disrupting biometric image capture, comprising:
(a) a frame configured in an eyewear form factor, the frame comprising a bridge, lens rims, and temple arms;
(b) a plurality of infrared emitters embedded in and distributed around said frame, wherein said plurality comprises at least sixteen emitters and not more than thirty-two emitters, said emitters being located at the bridge, along lower rim portions adjacent to the cheeks, at frontal portions of the temples, and at rearward portions of the temple arms to provide wrap-around coverage of a wearer's face;
(c) each infrared emitter configured to emit light within a spectral band between about 780 nm and about 1100 nm, a controller operatively coupled to the emitters and configured to selectively activate subsets of emitters in randomized or sensor-responsive patterns, including variations in duty cycle, pulse width, and sequence, to prevent machine-learning reconstruction of facial features;
(d) a power subsystem operatively coupled to the frame, the power subsystem comprising at least one of: an integrated power source within the frame, or an external power source coupled through a connector at a temple arm, enabling higher sustained output for daylight operation;
(e) a thermal management feature integrated into the frame, including one or more ventilation slots or equivalent structures to dissipate heat generated by the plurality of emitters;
(f) wherein emission of said plurality of emitters disrupts biometric recognition systems including facial recognition algorithms, by obscuring or distorting image capture of the wearer's facial features under varied lighting conditions, including daylight;
(g) wherein said emission further disrupts structured-light and time-of-flight depth sensing systems by introducing non-coherent infrared patterns and saturating depth-mapping sensors, thereby corrupting three-dimensional facial feature reconstruction;
(h) wherein said controller is configured to vary emission timing relative to anticipated rolling-shutter sensor exposures, producing frame-to-frame inconsistencies unrecoverable by temporal averaging algorithms;
(i) wherein said controller adjusts emitter output to maintain disruption across ambient illuminance levels between at least about 200 lux and about 10,000 lux; wherein at least a subset of said emitters are configured to deliver peak radiant power of at least 5 watts per diode, enabling disruption under direct daylight conditions.

3. The device of claim 2, wherein the plurality of emitters comprises exactly twenty-four (24) emitters distributed as: five at a bridge region, four along a left lower rim portion adjacent a cheek, four along a right lower rim portion adjacent a cheek, three at a left frontal temple portion, three at a right frontal temple portion, two at a left rear temple arm portion, and two at a right rear temple arm portion, to provide wrap-around facial coverage.

4. The device of claim 2, wherein each infrared emitter is configured to emit principally within about 850 and about 950 nm.

5. The device of claim 2, wherein the plurality of emitters collectively provides multi-band emission, including a first band centered at about 850 nm and about 880 nm and a second band centered at about 930 nm and about 950 nm, each with a full width at half maximum (FWHM) of ≤40 nm.

6. The device of claim 2, wherein the controller is configured to generate pseudo-random activation sequences using a seeded random number generator and to vary duty cycle and pulse width per emitter independently to reduce temporal periodicity detectable by recognition pipelines.

7. The device of claim 6, wherein the controller modulates emitters using pulse-width modulation in a frequency range of about 100 Hz to about 20 kHz, with per-emitter duty cycles between about 10% and about 90% and temporal jitter of +5-15%.

8. The device of claim 2, further comprising an ambient light sensor (ALS) having a spectral response spanning about 400 and about 1100 nm, the controller being configured to sample the ALS at ≥100 Hz and to switch between a daylight mode and a low-light mode based on measured illuminance thresholds.

9. The device of claim 2, wherein thermal management features comprise vent slots formed in the bridge and temple portions, each slot having a width between about 0.3 mm and about 1.5 mm and a length between about 3 mm and about 10 mm, with an array density of at least four slots per temple.

10. The device of claim 9, further comprising a thermally conductive path from at least the temple-mounted emitters to a heat spreader formed of graphite sheet, aluminum, copper, or thermally conductive polymer, disposed within the temple arm.

11. The device of claim 2, wherein the power subsystem comprises an external power source releasably coupled at a temple connector via a reversible multi-contact interface and a two-conductor shielded or braided cable, the external source providing a nominal output between about 5 V and about 12 V.

12. The device of claim 11, wherein the controller regulates emitter current via constant-current drivers with per-channel resolution of ≥8 bits, and monitors pack voltage and current to maintain output within a daylight operating envelope.

13. The device of claim 2, wherein the controller is configured to partition the plurality of emitters into emitter groups comprising at least a bridge group, left cheek group, right cheek group, left temple group, right temple group, left rear group, and right rear group, and to phase-stagger the groups to avoid constructive interference patterns.

14. The device of claim 2, wherein the bridge-located emitters are tilted downward by about 5 to about 15° relative to a horizontal plane of the frame, cheek-adjacent emitters are tilted upward by about 5 to about 20°, and temple-front emitters are toed-in by about 10 to about 25° toward a sagittal plane of the wearer, thereby increasing coverage across yaw and pitch variation.

15. The device of claim 2, wherein at least a subset of emitters are equipped with integrated optics providing distinct angular dispersions, including wide (≥60° FWHM), intermediate (30-60° FWHM), and narrow (≤30° FWHM) emission.

16. The device of claim 2, wherein the controller is further configured to avoid flicker perceptible to a human by constraining fundamental modulation components to ≥200 Hz while maintaining higher-frequency content sufficient to degrade rolling-shutter sensors.

17. The device of claim 2, further comprising a temperature sensor disposed within a temple arm and coupled to the controller, the controller being configured to reduce emitter drive or shut down selected groups upon a sensed temperature exceeding a first threshold and to shut down all emitters upon a second, higher threshold.

18. The device of claim 2, wherein at least one sensor comprises a near-infrared photodiode with a bandpass filter centered between about 850 and about 950 nm configured to detect retroreflective glints indicative of camera optics, the controller responsive thereto to prioritize activation of temple-front and bridge groups.

19. The device of claim 2, wherein the eyewear frame comprises matte black, low-gloss exterior surfaces and anti-reflective inner lens coatings to reduce secondary reflections into imaging sensors.

20. The device of claim 2, wherein the controller implements a blue-noise or Poisson-disk temporal/spatial distribution of activations so that no emitter group repeats within a fixed window, thereby reducing spatiotemporal regularity.

21. The device of claim 2, wherein the controller logs operating mode, emitter group activity, ALS values, and temperature to non-volatile memory for compliance and performance tuning.

22. The device of claim 2, wherein the external power source includes a mechanical latch or magnetic retention to the temple interface to prevent accidental decoupling during operation.

23. The device of claim 2, wherein the ALS thresholds and emitter-group schedules are user-configurable via a wired service interface during provisioning and thereafter locked by secure configuration.

24. The device of claim 2, wherein the emitter groups are phase-shifted relative to one another by about 15 to about 120 degrees of a base modulation period to minimize coherent bands in captured imagery.

25. The device of claim 2, wherein the spectral band is adaptively selected between about 780 nm to about 880 nm, about 880 nm to about 980 nm, and about 980 nm to about 1100 nm based on ambient spectrum or sensor feedback.

26. The device of claim 2, wherein the controller enforces output limits consistent with eye-safety exposure guidelines for near-infrared emission.

27. A method of disrupting biometric recognition of a wearer, comprising:
(a) emitting infrared light from a plurality of emitters embedded in an eyewear frame, wherein said plurality comprises at least sixteen emitters distributed at a bridge portion, cheek-adjacent rim portions, frontal temple portions, and rearward temple arm portions of the eyewear frame, to provide wrap-around coverage of the wearer's face;
(b) emitting said infrared light within a spectral band between about 780 nm and about 1100 nm, corresponding to wavelengths detectable by imaging sensors used in facial recognition systems;
(c) controlling activation of the emitters with a controller configured to: vary activation in randomized or sensor-responsive patterns, modulate duty cycle, pulse width, or sequence of emitters, thereby preventing machine-learning systems from reconstructing the wearer's facial features;
(d) powering the plurality of emitters via a power subsystem comprising at least one of: an integrated power source within the eyewear frame, or an external power source coupled to a connector at a temple arm;
(e) dissipating heat generated by the emitters using thermal management features integrated into the eyewear frame;
(f) whereby the emission of said plurality of emitters obscures or distorts biometric recognition systems, including AI-based facial recognition algorithms, across varied lighting conditions including daylight;
(g) whereby said emission further interferes with structured-light and time-of-flight depth sensing by injecting randomized infrared signals that distort or saturate projected-dot or pulsed-return depth maps;
(h) wherein controlling activation further comprises varying emission timing relative to rolling-shutter sensor exposures to produce frame-to-frame inconsistencies unrecoverable by temporal averaging algorithms;
(i) wherein powering and control maintain disruption across ambient illuminance levels between at least about 200 lux and about 10,000 lux;
(j) wherein said plurality of emitters includes at least a subset configured to deliver peak radiant power of at least about 5 watts per diode.

28. The method of claim 27, further comprising sampling an ambient light sensor (ALS) at ≥100 Hz, classifying a scene as daylight when illuminance exceeds a first threshold and as low-light when illuminance falls below a second threshold.

29. The method of claim 27, wherein emitting comprises activating at least twenty-four emitters distributed around the bridge, cheek rims, temple fronts, and rear temple arms to provide wrap-around coverage.

30. The method of claim 27, wherein controlling activation comprises generating pseudo-random sequences and varying duty cycle and pulse width per emitter so that repeated sequences do not recur within a predefined temporal window.

31. The method of claim 27, further comprising selecting a spectral sub-band from about 850 nm to about 950 nm or about 930 nm to about 980 nm responsive to ambient measurements to maximize sensor saturation while limiting human detectability.

32. The method of claim 27, further comprising phase-staggering emitter groups such that no two adjacent groups reach peak output simultaneously.

33. The method of claim 27, further comprising monitoring a temperature sensor and reducing drive current to at least one emitter group when a first temperature threshold is exceeded and disabling all emitters when a second temperature threshold is exceeded.

34. The method of claim 27, wherein controlling activation comprises maintaining modulation fundamentals ≥200 Hz to avoid perceptible flicker while injecting higher-frequency components to affect rolling-shutter exposure.

35. The method of claim 27, further comprising detecting retroreflective glints via a near-infrared photodiode and directing increased output to bridge and temple-front groups in response.

36. The method of claim 27, further comprising logging operating parameters including ambient light level, emitter group schedules, spectral band selections, and temperature metrics for compliance or tuning.

37. The method of claim 27, wherein the external power source is coupled to a temple interface and negotiated to provide an output between about 5 V and about 12 V, and wherein the controller limits total current to a preset budget in daylight mode.

38. The method of claim 27, further comprising computing a blue-noise activation mask across emitter positions so that spatial adjacency is minimized over time.

39. The method of claim 27, further comprising adapting emitter angles via selection of sub-groups oriented downward (bridge), upward (cheeks), and inward (temples) responsive to head pose or ambient glare.

40. The method of claim 27, further comprising selecting spectral bands between about 780 nm to about 880 nm, about 880 nm to about 980 nm, and about 980 nm to about 1100 nm based on ALS spectrum or external sensor feedback.

41. The method of claim 27, further comprising enforcing exposure limits consistent with near-infrared eye-safety guidelines during all operating modes.
